(19) United States
(12) Patent Application Publication
(10) Pub. No.: US 2024/0420989 A1
(43) Pub. Date: Dec. 19, 2024

(54) CHIP TWEEZERS

(71) Applicant: Government of the United States of America, as represented by the Secretary of Commerce, Gaithersburg, MD (US)

(72) Inventor: Jeffrey Taylor Chiles, Louisville, CO (US)

(21) Appl. No.: 18/745,476

(22) Filed: Jun. 17, 2024

Related U.S. Application Data
(60) Provisional application No. 63/521,428, filed on Jun. 16, 2023.

(51) Int. Cl. H01L 21/687; B25B 9/02

(52) U.S. Cl. CPC H01L 21/687; B25B 9/02

(57) ABSTRACT

Chip tweezers for handling microchips include a body portion having a pair of arms coupled together at a proximal end and extending toward a distal end, wherein the arms are moveable towards and away from each other; and a head portion located at the distal end, the head portion including a pair of V-grooves disposed parallel to each other with open sides facing each other, each rigidly connected to a respective arm of the pair of arms.

### RELATED APPLICATIONS

This application claims the benefit of U.S. Provisional Patent Application Ser. No. 63/521,428 (filed Jun. 16, 2023), which is herein incorporated by reference in its entirety.

### FEDERALLY-SPONSORED RESEARCH AND DEVELOPMENT

This invention was made with United States Government support from the National Institute of Standards and Technology (NIST), an agency of the United States Department of Commerce. The Government has certain rights in this invention.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF INVENTION

The present invention relates generally to handling chips, and more particularly to tweezers for handling chips.

### BACKGROUND

Chip tweezers can be used in research and development for optoelectronic, superconducting and semiconductor device fabrication. In many fabs across the country, chip-level handling is required during process development or end-stage device handling.

### SUMMARY OF INVENTION

Exemplary chip tweezers, described herein, firmly handle semiconductor chips without applying force to the top or bottom surfaces. The chip tweezer can include an elongated V-groove aligned with the length of the chip tweezers. The chip tweezers optionally can include a stub at one end of the groove, allowing the chips to be submerged in beakers without concern over them falling out of the back.

According to one aspect of the invention, chip tweezers for handling microchips include a body portion having a pair of arms coupled together at a proximal end and extending toward a distal end, wherein the arms are moveable towards and away from each other; and a head portion located at the distal end, the head portion including a pair of V-grooves disposed parallel to each other with open sides facing each other, each rigidly connected to a respective arm of the pair of arms.

Optionally, the pair of arms are configured to provide resistive spring force against movement to and/or from each other.

Optionally, the arms are configured to extend, cantilevered, longitudinally from a rigid connection to each other at the proximal end and cross over each other at a cross-over point distal the connection point, thereby providing a spring force tending to resist a squeezing force applied proximal the cross-over point and providing a spring force tending to close the head portion to provide a passive force on a chip within the V-grooves.

Optionally, the V-grooves can be positioned such that a longitudinal axis of the V-grooves is laterally offset to a longitudinal axis of the body portion.

Optionally, V-grooves are positioned such that a longitudinal axis of the V-grooves is parallel to a longitudinal axis of the body portion of the tweezers.

Optionally, the V-grooves each include a respective stub at the distal end, extending laterally inward from the respective V-groove, thereby tending to prevent a chip from sliding out of the head portion in a distal direction.

The foregoing and other features of the invention are hereinafter described in greater detail with reference to the accompanying drawings.

### BRIEF DESCRIPTION OF THE DRAWINGS

FIG. 1 shows an isometric view of exemplary chip tweezers.

FIG. 2 shows a side orthographic view of exemplary chip tweezers.

FIG. 3 shows a top orthographic view of exemplary chip tweezers.

FIG. 4 shows a front orthographic view of exemplary chip tweezers.

FIG. 5 shows a rear orthographic view of exemplary chip tweezers.

FIG. 6 shows a detail view of a V-groove with stub of exemplary chip tweezers.

FIG. 7 shows a front orthographic view of exemplary chip tweezers without stubs.

FIG. 8 shows a rear orthographic view of exemplary chip tweezers without stubs.

### DETAILED DESCRIPTION

Exemplary chip tweezers, described herein, firmly handle semiconductor chips without applying force to the top or bottom surfaces. The chip tweezer may include an elongated V-groove generally parallel with the length of the chip tweezers, or at an offset. The chip tweezers optionally can include a stub at one end of the groove, allowing the chips to be submerged in beakers without concern over them sliding out of the gripper end.

The chip tweezers may be made in any number of ways including, for example, by injection molding or by additive manufacturing such as with stereolithography-based 3D printing, allowing variations of the design to be created in a cleanroom environment. The chip tweezers may be any appropriate size for handling chips, and may be, for example, sized to grip chips approximately 1 cm×1 cm×0.4 mm thickness that can be comfortably and securely held in the end grippers of the chip tweezers while being subjected to various tests that would be typical of semiconductor processing in a fabrication facility, including, e.g.:
(1) Acetone/IPA/Nitrogen cleaning: successive spraying of solvents at high pressure, followed by nitrogen drying of the entire sample. The chip tweezers may hold the sample firmly despite low force applied to it.
(2) High power sonication: The sample may be held in the chip tweezers and submerged facing downward in a beaker while avoiding direct contact with the glass wall of the container. The chip tweezers with the sample may be submerged in IPA and sonicated at high power (for 30 seconds, e.g.) and hold the chip the whole time. This would not be practical with conventional tweezers.
(3) Aggressive chemicals: A sample submerged in a 10% hydrochloric acid solution while being held by the chip tweezers in the same manner. Exemplary chip tweezers are preferably constructed to withstand such immersion in acid. For example, being 3D-printed with polypropylene would allow chip tweezers to not degrade or lose grip on the sample.

Exemplary chip tweezers may be capable of manipulating small samples of various materials. Exemplary chip tweezers solve the unmet need for reliable gripping of small, thin samples that have at least two parallel sides. Example items that can be held by the chip tweezers include semiconductor chips, glass chips, dielectric chips, and the like.

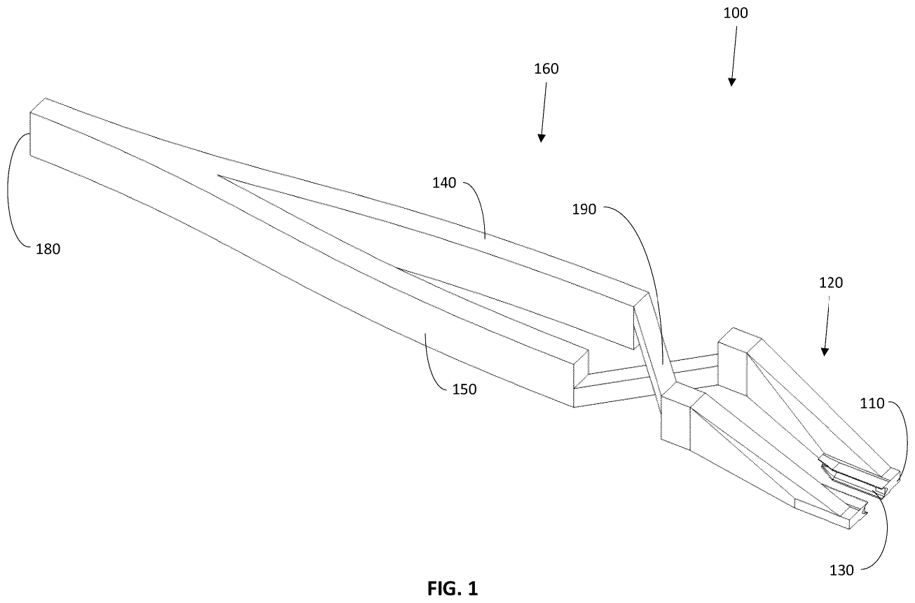

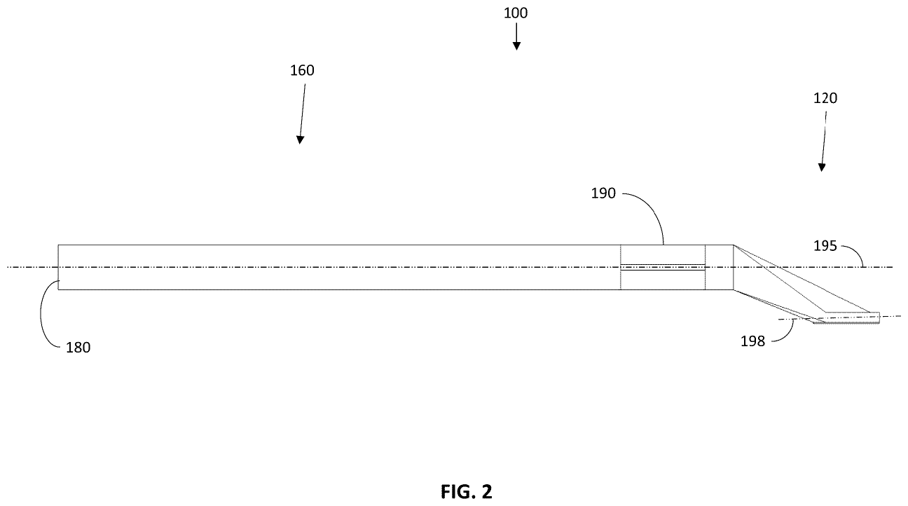

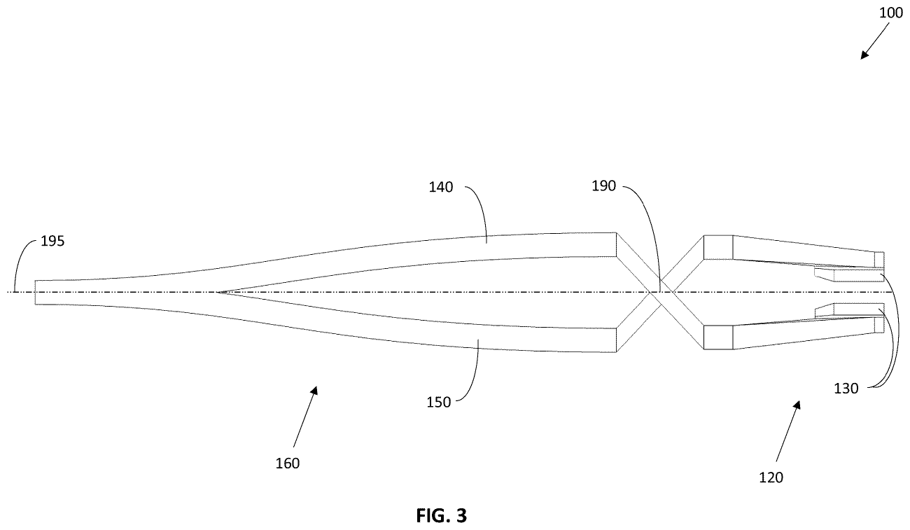

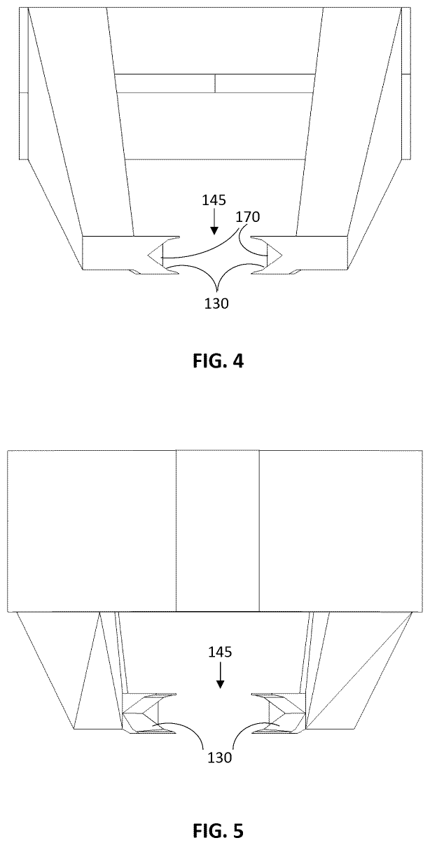

Referring now to FIG. 1-6, an exemplary chip tweezer 100 is shown. The chip tweezers include a head portion 120 at a distal end 110 that includes a pair of V-grooves 130 that are disposed parallel to each other with open sides facing each other, disposed on each arm 140, 150 and that are oriented to oppose each other in the gap 145 between the two arms 140, 150. In this way, a (sample not shown) can be positioned and gripped between the two arms 140, 150 without the chip tweezers coming into direct contact with either the top or bottom surface of the sample. The V-grooves are positioned such that the V-shape tends to prevent movement of (and passively-center) a relatively planar object held therebetween in a direction perpendicular to a longitudinal axis 195 of the tweezers (and a longitudinal axis 198 of the V-grooves) and perpendicular to the direction of relative movement between the V-grooves.

Arms 140, 150 may be connected at or near proximal end 180 and configured in any conventional way to provide resistive spring force against movement. In the preferred embodiment shown, the arms 140, 150 are configured to extend, cantilevered, longitudinally from a rigid connection to each other at the proximal end 180 and cross over each other at 190. This configuration provides a spring force tending to resist a squeezing force applied proximal the cross-over point 190. Such a squeezing force would open the head portion 120 to allow, for example, the accepting or releasing of a chip from the v-grooves 130. Additionally, this configuration would provide a spring force tending to close the head portion 120, thereby providing a passive force on a chip within the v-grooves 130 (of width greater than the spacing between the v-grooves at a resting position of the tweezers 100). Of course, other configurations may be consistent with the invention (such as, for example, the arms of an exemplary tweezer being fixed with a rotatable link and rotatable about an axis perpendicular to its longitudinal axis with either no spring force or a spring force provided by a separate spring such as a coil spring or leaf spring).

Optionally, as shown, the V-grooves 130 can be positioned offset (at a height lower than) to the length of the body portion 160 of the chip tweezers to capture the sample and to provide better ergonomics during use. Additionally, or alternatively, the V-grooves 130 may be positioned such that the longitudinal axis of the V-grooves is oblique to the longitudinal axis of the body of the tweezers (not shown). Instead, the V-grooves 130, as shown, may be positioned such that their longitudinal axis is parallel to the longitudinal axis of the body of the tweezers.

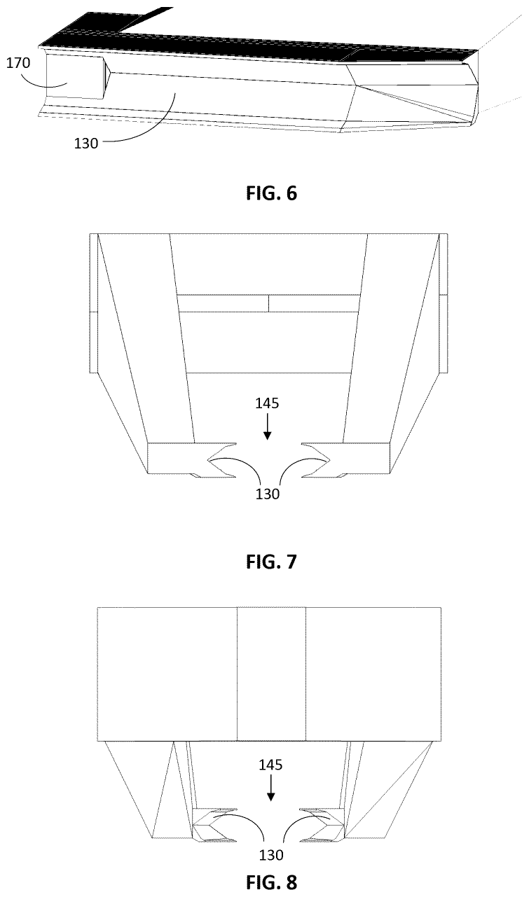

Optionally, as shown in detail in FIG. 6, exemplary chip tweezers may include stubs 170 at distal ends 110 of the V-grooves 130. Here, the distal end 110 of the chip tweezers is at the V-grooves, and the proximal end 180 of the chip tweezers is the end at which the two arms 140, 150 are joined. Stubs 170 terminate the V-grooves 130 at the distal end 110 and prevent the sample from sliding out in that direction by providing a positive stop against which a chip may rest when gripped in tweezers 100 within the V-grooves. Accordingly, the chip tweezers 100 can be used in various processes involving aggressive agitation with the proximal end 180 upright, and the distal end 110 pointed downward, gripping the sample while submerged in a liquid, for example.

Exemplary chip tweezers 200 are also shown without stubs in FIGS. 7 & 8. All other structures are identical to chip tweezers 100 and the above description of tweezers 100, except for that about stubs 170, is equally applicable to chip tweezers 200.

Conventional tweezers cannot reliably hold small, thin samples in the full range of use cases. Conventional textured flat-head tweezers with metal heads can produce microcracks on the chip corners and edges due to the high force required. Additionally, conventional metal tweezers cannot be used in most aggressive chemical environments such as etching solutions, wherein the chip is held in some other way or placed in the beaker by itself. This is undesirable and cumbersome, especially when retrieving or transferring the chip.

Exemplary chip tweezers overcome these limitations of conventional technology and hold the chip so that the chip can be disposed directly in a solution, taken out, rinsed, and dried without any transfer necessary. Because of the effectiveness of the V-groove at passively-centering and gripping the sample, it can achieve this with very little force.

Exemplary chip tweezers provide more reliable sample retention than conventional tweezers and can be used on critical prototypes and in-process samples, without concern for accidentally dropping them during processing. The chip tweezers provide rapid and simple sample manipulation in rapidly developing processes and reliability of sample manipulation.

Exemplary chip tweezers can be used in research and development for optoelectronic, superconducting and semiconductor device fabrication. In many fabs across the country, chip-level handling is required during process development or end-stage device handling, and the chip tweezers reduce waste by avoiding lost chips during handling and improve cleanliness by avoiding direct contact with the surface of the chips. In very sensitive processes, such as qubit fabrication, these features are highly desirable.

Elements of exemplary chip tweezers can be various sizes. Elements of exemplary chip tweezers can be made of a material that is physically or chemically resilient in an environment in which the chip tweezers are disposed. Exemplary materials include a metal, ceramic, thermoplastic, glass, semiconductor, and the like. The elements of exemplary chip tweezers can be made of the same or different material and can be physically joined.

Exemplary chip tweezers can be made in various ways. It should be appreciated that exemplary chip tweezers include a number of mechanical components, wherein such components can be interconnected and placed in communication by physical interconnects or may be monolithic. As a result, the chip tweezers can be disposed in a terrestrial environment or space environment. According to an embodiment, the elements of the chip tweezers are formed using 3D printing although the elements of the chip tweezers can be formed using other methods, such as injection molding or machining a stock material such as block of material that is subjected to removal of material such as by cutting, laser oblation, and the like. Accordingly, the chip tweezers can be made by additive or subtractive manufacturing.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. Chip tweezers for handling microchips comprising:
a body portion having a pair of arms coupled together at a proximal end and extending toward a distal end, wherein the arms are moveable towards and away from each other; and
a head portion located at the distal end, the head portion including a pair of V-grooves disposed parallel to each other with open sides facing each other, each rigidly connected to a respective arm of the pair of arms.

2. The chip tweezers of claim 1, wherein the pair of arms are configured to provide resistive spring force against movement to and/or from each other.

3. The chip tweezers of claim 2, wherein the arms are configured to extend, cantilevered, longitudinally from a rigid connection to each other at the proximal end and cross over each other at a cross-over point distal the connection point, thereby providing a spring force tending to resist a squeezing force applied proximal the cross-over point and providing a spring force tending to close the head portion to provide a passive force on a chip within the V-grooves.

4. The chip tweezers of claim 1, wherein the V-grooves can be positioned such that a longitudinal axis of the V-grooves is laterally offset to a longitudinal axis of the body portion.

5. The chip tweezers of claim 1, wherein the V-grooves are positioned such that a longitudinal axis of the V-grooves is parallel to a longitudinal axis of the body portion of the tweezers.

6. The chip tweezers of claim 1, wherein the V-grooves each include a respective stub at the distal end, extending laterally inward from the respective V-groove, thereby tending to prevent a chip from sliding out of the head portion in a distal direction.
